(19) United States
(12) Patent Application Publication
(10) Pub. No.: US 2026/0052823 A1
(43) Pub. Date: Feb. 19, 2026

(54) LED Display for Use in High Impact Environments

(71) Applicant: Global Product Sources, LLC, Madison, TN (US)

(72) Inventor: Jeremy D. Lee, Madison, TN (US)

(73) Assignee: Global Product Sources, LLC, Madison, TN (US)

(21) Appl. No.: 19/243,039

(22) Filed: Jun. 19, 2025

Related U.S. Application Data
(60) Provisional application No. 63/682,359, filed on Aug. 13, 2024.

(51) Int. Cl. H10H 29/854; F16F 3/10; H05K 5/02

(52) U.S. Cl. CPC H10H 29/854; F16F 3/10; H05K 5/0217; F16F 2224/0225

(57) ABSTRACT

An LED display unit for use in high impact environments includes a frame disposed within a housing, with multiple LED display modules attached to the frame. Each display module includes a support structure, a foam shock absorber, multiple spring-biased shock absorbers, a printed circuit board, and a front protective panel. The foam shock absorber and the spring-biased shock absorbers are disposed between the frame and a rear surface of the support structure. The printed circuit board, which is attached to a front surface of the support structure, includes an array of LEDs that are covered by the front protective panel. The combination of the foam shock absorber and the spring-biased shock absorbers provides adequate shock absorption to prevent damage to the printed circuit board when the front protective panel is impacted by a foreign object.

### FIELD

This invention relates to light emitting diode (LED) display panels used in stadiums and arenas for sporting events for advertising and informational purposes. More particularly, the invention relates to an LED display unit having a structure that protects the array of LEDs and related circuitry from damage due to object impacts during sporting events.

### BACKGROUND

Large LED display boards have become ubiquitous in sports venues. Such boards provide advertising and other visual information during a game to the attendees of the venues. Some of the boards are placed very near the boundaries of the field or court on which the game is being played. This placement provides exposure to a large number of viewers, both at the game and watching on television. For example, in Major League Baseball (MLB) games, there is an LED display board directly behind the home plate of every stadium. This board is in the frame of the television camera looking over the pitcher toward home plate for most of the time during a game. Other such boards are usually positioned along the outfield walls. Very large-format screens are usually placed behind the outfield stands.

One problem with having these display boards in such close proximity to the field is the probability of impact damage from the baseballs. A baseball coming off a bat may be traveling at speeds of up to about 100 mph and may impact a display board with a significant force. Such impacts often damage the LEDs and circuitry that lay just below the surface of the display board. The cost of repairing the resulting damage is a significant expense for owners of baseball stadiums.

What is needed are structural means for reducing impact damage to LED display boards in MLB stadiums and other sporting venues, without interfering with the visual quality of the display.

### SUMMARY

The above and other needs are met by an LED display unit for use in high impact environments. The LED display unit includes a frame disposed within a housing, with multiple display modules attached to the frame. Each display module includes a support structure, a foam shock absorber, multiple spring-biased shock absorbers, a printed circuit board, and a front protective panel. The foam shock absorber and the spring-biased shock absorbers are disposed between the frame and a rear surface of the support structure. The printed circuit board, which is attached to a front surface of the support structure, includes an array of LEDs that are covered by the front protective panel. The combination of the foam shock absorber and the spring-biased shock absorbers provides adequate shock absorption to prevent damage to the printed circuit board when the front protective panel is impacted by a foreign object.

In some embodiments, the foam shock absorber comprises Ethylene Vinyl Acetate (EVA) foam.

In some embodiments, the thickness of the foam shock absorber ranges from about 1 inch to 2 inches.

In some embodiments, each display module is rectangular, and there are four spring-biased shock absorbers, each disposed adjacent a corresponding corner of the rectangular display module.

In some embodiments, each of the spring-biased shock absorbers comprises a spring-biased piston portion within a sleeve portion.

In some embodiments, there are multiple apertures in the foam shock absorber, and each of the spring-biased shock absorbers is disposed within a corresponding one of the multiple apertures.

In some embodiments, the front protective panel is spaced away from the array of LEDs by about 2 mm.

In some embodiments, the front protective panel includes multiple posts extending from its rear surface, and the printed circuit board includes multiple apertures that receive the posts. The front surface of the support structure includes multiple sockets that receive the posts extending through the apertures in the printed circuit board.

### BRIEF DESCRIPTION OF THE DRAWINGS

Further advantages of the invention are apparent by reference to the detailed description in conjunction with the figures, wherein elements are not to scale so as to more clearly show the details, wherein like reference numbers indicate like elements throughout the several views, and wherein:

FIG. 1 depicts a front view of an LED display unit according to an embodiment of the invention;

FIG. 2 depicts a rear view of the LED display unit;

FIG. 3A depicts a front exploded view of the LED display unit;

FIG. 3B depicts a rear exploded view of the LED display unit;

FIG. 4A depicts a rear view of six individual display modules of the LED display unit with a rear frame attached;

FIG. 4B depicts a rear view of six individual display modules of the LED display unit with the rear frame detached;

FIG. 5A depicts a rear view of six individual display modules of the LED display unit with a shock absorber attached;

FIG. 5B depicts a rear view of six individual display modules of the LED display unit with the shock absorber detached;

FIG. 5C depicts a rear view of six individual display modules of the LED display unit;

FIG. 6A depicts a rear view of one of the display modules;

FIG. 6B depicts an exploded rear view of one of the display modules with spring-biased shock absorbers;

FIG. 7A depicts a front view of one of the display modules;

FIG. 7B depicts a front view of one of the display modules with its front protective panel detached;

FIG. 7C depicts an exploded front view of one of the display modules;

FIG. 7D depicts an exploded rear view of one of the display modules;

FIG. 8 depicts the rear surface of the front protective panel of one of the display modules;

FIG. 9 depicts the front surface of the printed circuit board of one of the display modules;

FIG. 10 depicts the front surface of the support structure of one of the display modules; and

FIG. 11 depicts a cross-sectional view of the front protective panel, printed circuit board, and support structure of a portion of a display module.

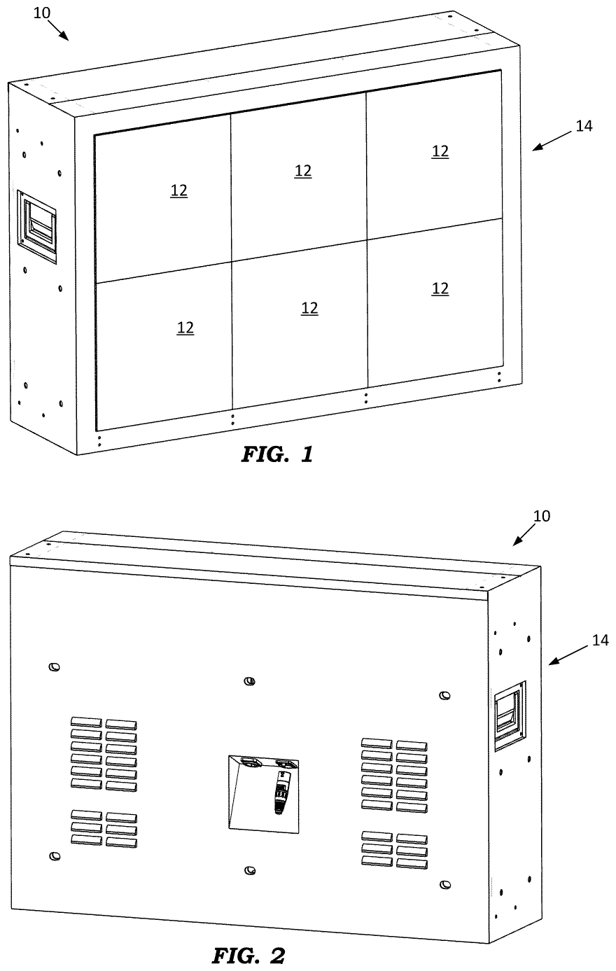

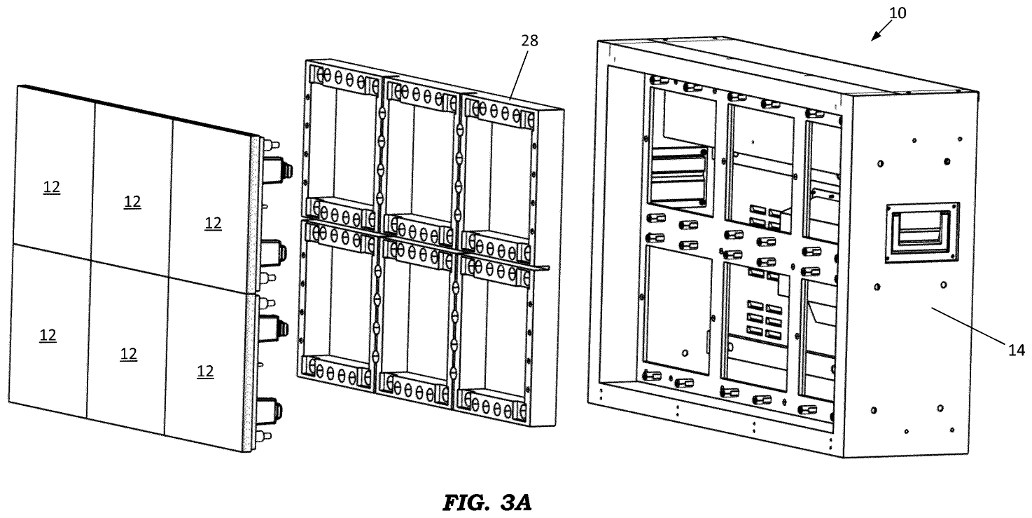

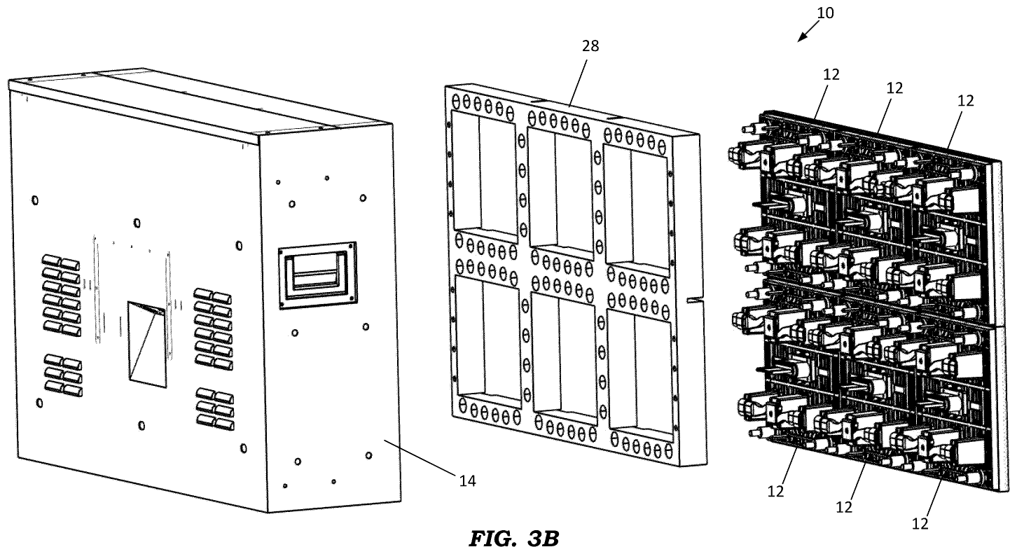

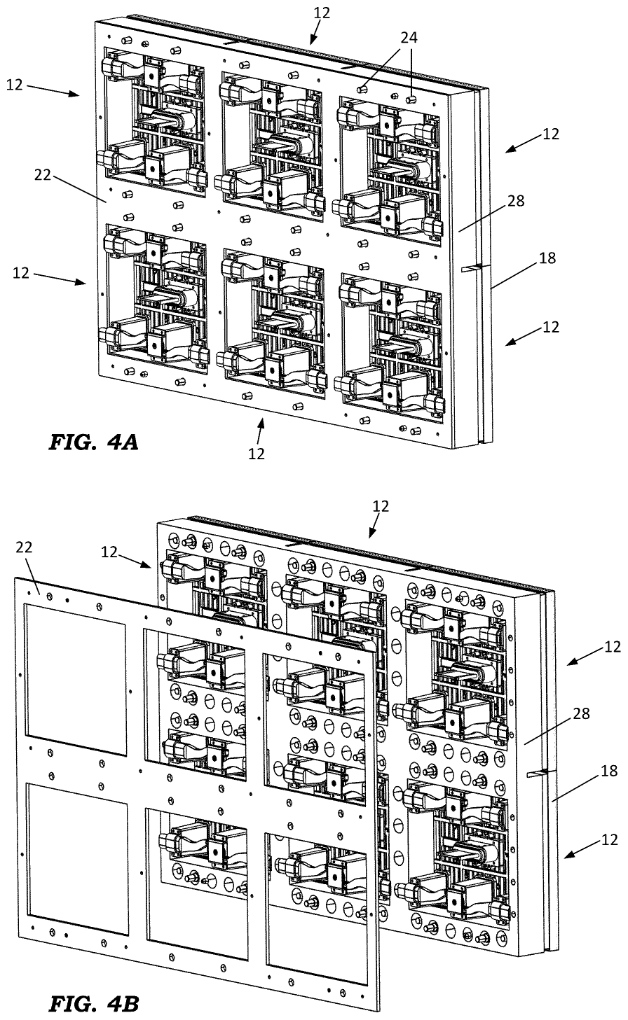

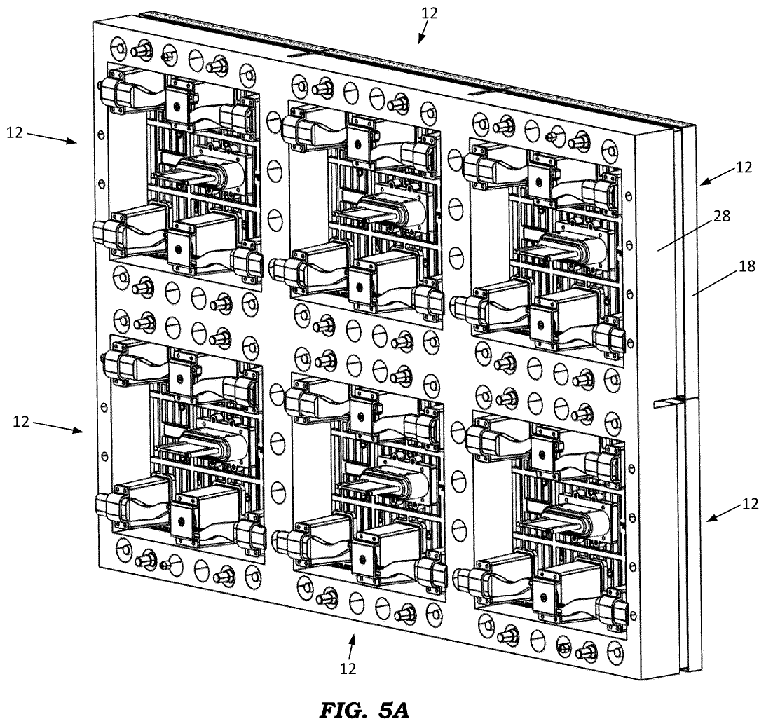

### DETAILED DESCRIPTION

The figures depict a preferred embodiment of an LED display unit 10 for use in high impact environments. The unit 10 comprises a housing 14, preferably formed from steel, that supports an array of LED display modules 12. Some embodiments of the display unit 10 described herein include six display modules 12 in a 3×2 array. However, it should be appreciated that the unit 10 could include any number of display modules in various array configurations.

Each display module 12 includes a printed circuit board (PCB) 16 on which thousands of LEDs are mounted in a rectangular grid. In one embodiment, there are 1764 LEDs in each module 12. Each display module 12 also includes circuitry for distributing power and control signals to each LED. The general components and functionality of such circuitry are well understood by those of ordinary skill in the art.

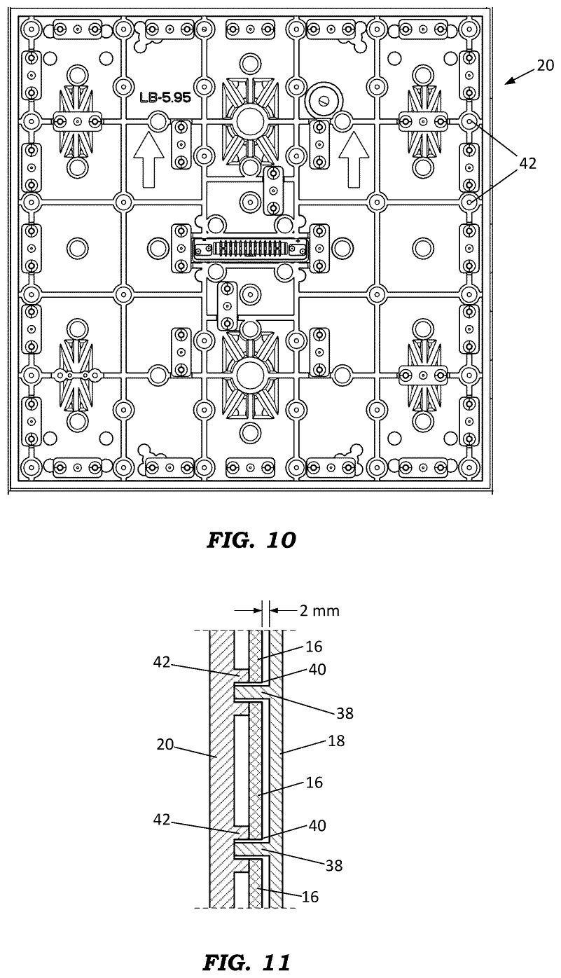

Each display module 12 includes a front protective panel 18 and a support structure 20. The support structure 20 supports the PCB 16 and houses some of the circuitry for distributing power and control signals. The front protective panel 18 covers the front of the display module 12 to protect the LEDs on the front of the PCB 16. The front protective panel 18 is preferably formed from polycarbonate, which has the needed impact strength to withstand about 5500 lb of force without cracking and which has sufficient transparency to the light from the LEDs. The thickness of the front panel 18 is about 3 mm in a preferred embodiment, but may vary from about 2 mm to 5 mm in other embodiments. The spacing between the front panel 18 and the LEDs on the PCB 16 is only about 2 mm in preferred embodiments (see FIG. 11). This close spacing eliminates image distortion caused by reflections in conventional display panels, in which the front panels are spaced away from the LED arrays by one or more inches.

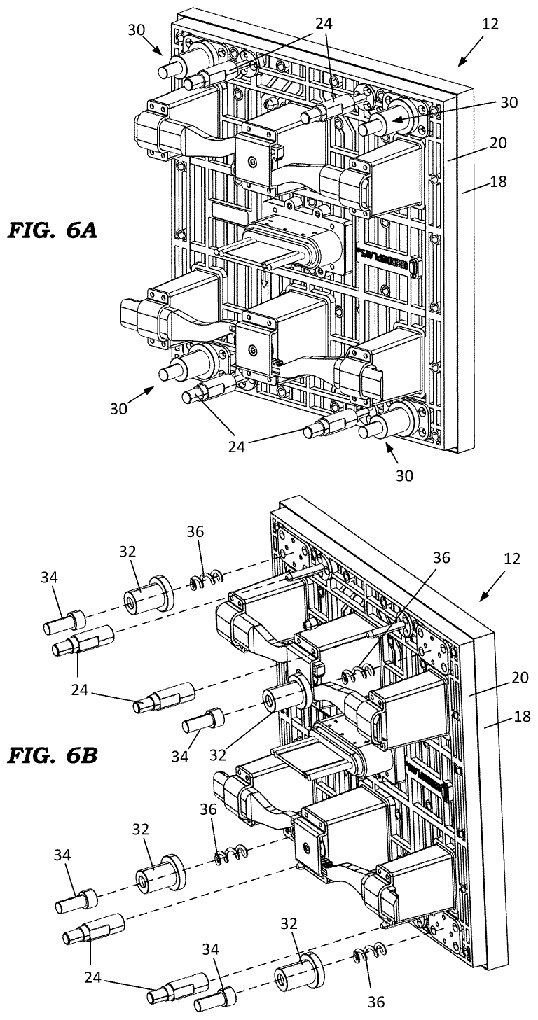

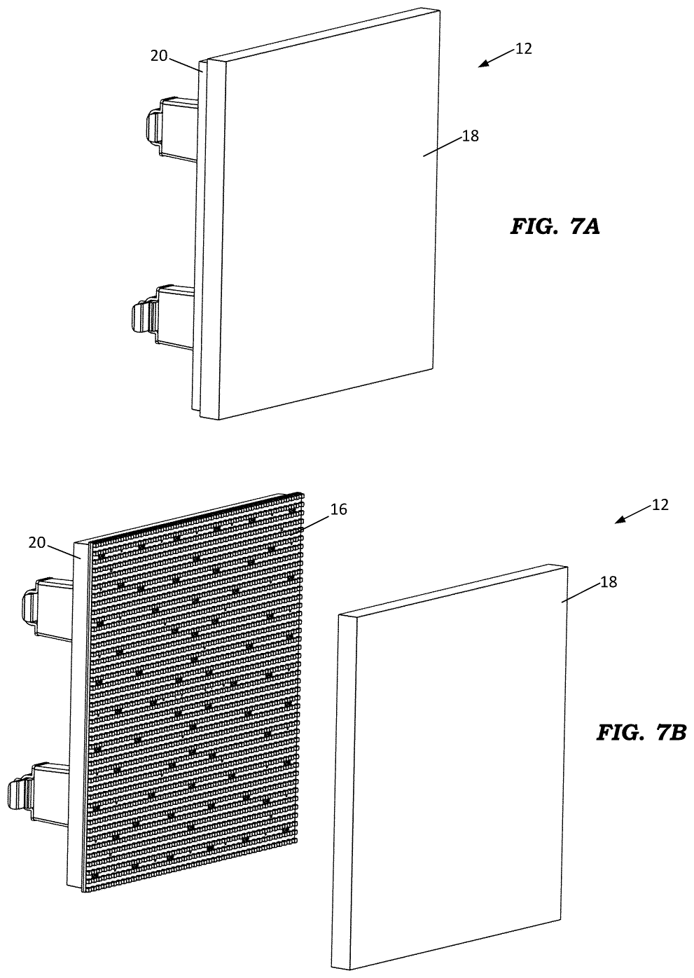

As shown in FIGS. 7D, 8 and 11, multiple posts 38 extend outward from the rear surface of the front protective panel 18. These posts 38 are distributed across the rear surface of the front protective panel 18 in an array that is preferably vertically and horizontally symmetrical. In the preferred embodiment, the posts 38 are integrally molded features of the front protective panel 18.

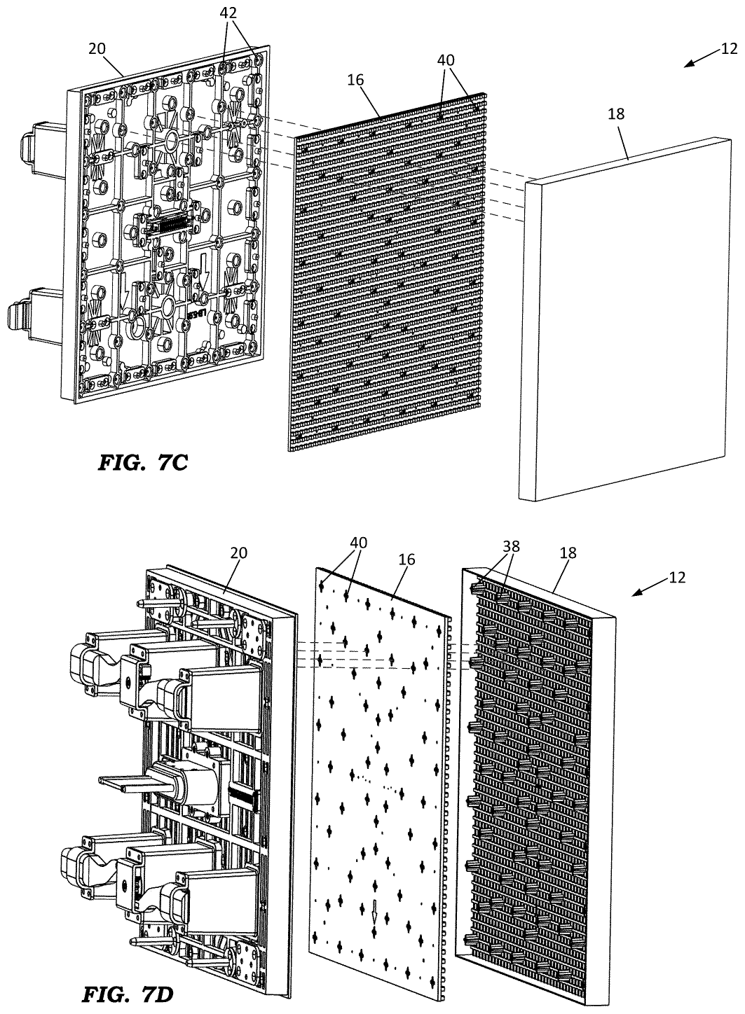

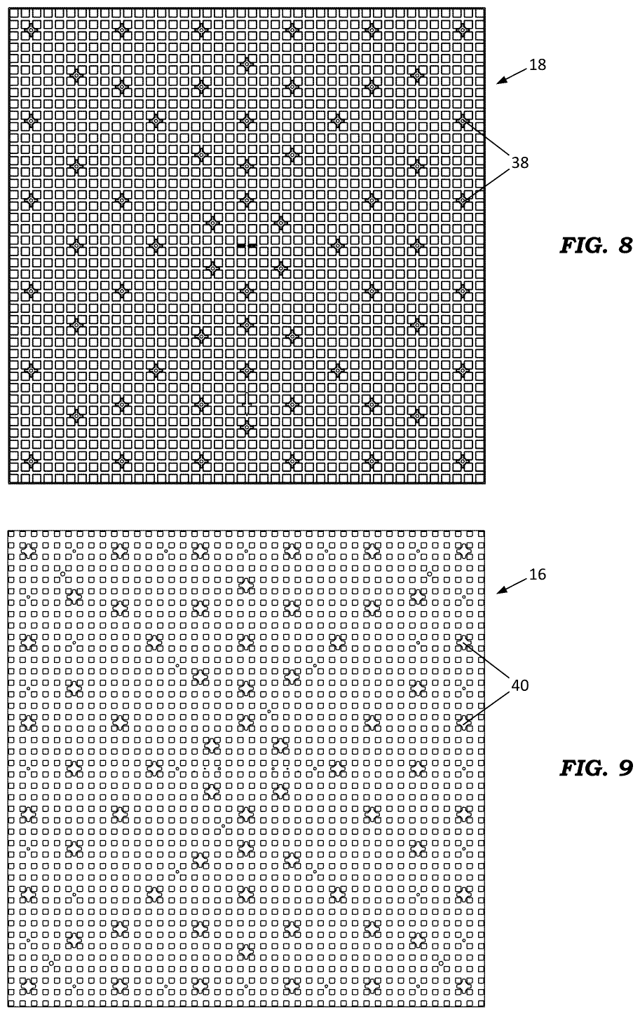

As shown in FIGS. 7C, 7D, 9 and 11, multiple apertures 40 are provided through the PCB 16 in locations that align with the locations of the posts 38 in the front protective panel 18. When the front protective panel 18 is attached to the display module 12, the posts 38 pass through the apertures 40 and are received in corresponding sockets 42 on the forward surface of the support structure 20. In the preferred embodiment, the sockets 42 are integrally formed in the support structure 20 during its molding or casting process. As shown in FIG. 11, when the posts 38 are abutted against the forward surface of the support structure 20 within the sockets 42, the rear surface of the front protective panel 18 is spaced away from the front surface of the LEDs on the PCB 16 by about 2 mm.

Each display module 12 is attached to a frame 22 by way of four threaded posts 24 that extend from the rear of the support structure 20, and nuts that secure the frame 22 to the posts 24. Filling the space between the frame 22 and the support structure 20 of each display module 12 is a foam shock absorber 28. In a preferred embodiment, the thickness of the foam shock absorber is between about 1 inch and 2 inch. Also in a preferred embodiment, the foam shock absorber 28 is formed from Ethylene Vinyl Acetate (EVA) having a density of about 930 kg/m³.

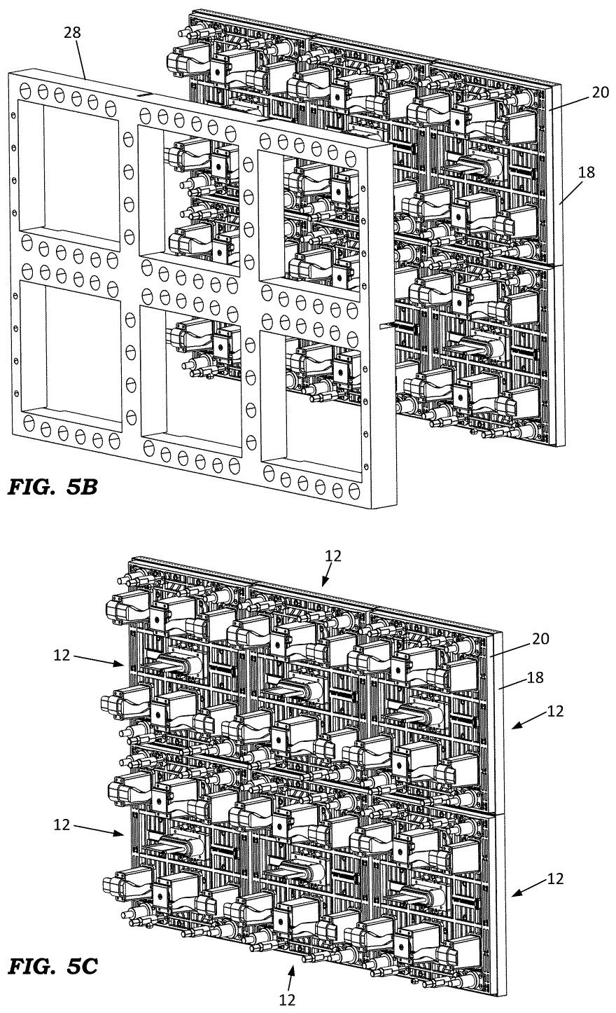

Also attached to the rear surface of the support structure 20 are four spring-biased shock absorbers 30, one of which is disposed near each corner of the support structure 20. As shown in FIG. 6B, each shock absorber 30 includes a piston portion 32 received within a sleeve portion 34. A spring 36 is provided within the sleeve portion 34 to bias the piston portion 32 outward. In a preferred embodiment, the spring 36 has a diameter of about 1 mm and provides a spring force of about 5.8 kg. When the display module 12 is attached to the frame 22, the outer end of the piston portion 32 contacts the frame 22. In a preferred embodiment, the range of travel of the piston portion 32 is about 1 inch, which defines the range of movement of the support structure 20 of the module 12 with respect to the frame 22 when a pushing force is applied to the front panel 18 of the module 12.

Testing has indicated that the combination of the spring-biased shock absorbers 30 and the foam shock absorber 28 reduces the impact force on the PCB 16 caused by a baseball striking the module 12 at speeds exceeding 100 mph by about 1800 Newtons.

Advantages of the LED display panel 10 described herein compared to conventional display panels include:
higher impact resistance;
reduced or eliminated downtime of advertisements, play clocks, etc., that are displayed;
longer lifetime due to waterproofing of LED modules; and
the front panel 18 may be in close proximity to the LEDs on the PCB 16, which eliminates the image distortions/reflections present in conventional display panels in which the LEDs must be spaced away from the front panel by one or more inches.

While the structure of the display unit 10 is specifically designed to handle impact from baseballs, it will be appreciated that the unit 10 could also be used for hockey, football, soccer, car racing, and other sports having the potential for impact damage to video display screens.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A light emitting diode (LED) display unit for use in high impact environments, the LED display unit comprising:
a frame disposed within a housing; and
a plurality of display modules attached to the frame, each display module comprising:
a support structure having a rear surface and a front surface;
a foam shock absorber disposed between the frame and the rear surface of the support structure;
a plurality of spring-biased shock absorbers disposed between the frame and the rear surface of the support structure;
a printed circuit board attached to the front surface of the support structure, the printed circuit board having an array of LEDs; and
a front protective panel covering the array of LEDs,
wherein the foam shock absorber and the plurality of spring-biased shock absorbers in combination provide shock absorption that prevents damage to the printed circuit board when the front protective panel is impacted by a foreign object.

2. The LED display unit of claim 1 wherein the foam shock absorber comprises Ethylene Vinyl Acetate (EVA) foam.

3. The LED display unit of claim 1 wherein a thickness of the foam shock absorber ranges from about 1 inch to 2 inches.

4. The LED display unit of claim 1 wherein each display module is rectangular, and the plurality of spring-biased shock absorbers comprise four spring-biased shock absorbers, each disposed adjacent a corresponding corner of the rectangular display module.

5. The LED display unit of claim 1 wherein each of the spring-biased shock absorbers comprises a spring-biased piston portion within a sleeve portion.

6. The LED display unit of claim 1 wherein each of the spring-biased shock absorbers is disposed within a corresponding one of a plurality of apertures in the foam shock absorber.

7. The LED display unit of claim 1 wherein the front protective panel is spaced away from the array of LEDs by about 2 mm.

8. The LED display unit of claim 1 wherein:
the front protective panel includes a plurality of posts extending from a rear surface of the front protective panel;
the printed circuit board includes a plurality of apertures through which are received the plurality of posts extending from the front protective panel; and
the front surface of the support structure includes a plurality of sockets that receive the posts extending through the apertures in the printed circuit board.

9. A light emitting diode (LED) display unit for use in high impact environments, the LED display unit comprising:
a frame disposed within a housing; and
a plurality of display modules attached to the frame, each display module being substantially rectangular in shape and comprising:
a support structure having a rear surface and a front surface;
a foam shock absorber disposed between the frame and the rear surface of the support structure, wherein the foam shock absorber has a plurality of apertures;
a plurality of spring-biased shock absorbers, each disposed within a corresponding one of the plurality of apertures in the foam shock absorber, wherein each of the spring-biased shock absorbers comprises a spring-biased piston portion within a sleeve portion, wherein at least four of spring-biased shock absorbers are disposed adjacent corresponding corners of the display module;
a printed circuit board attached to the front surface of the support structure, the printed circuit board having an array of LEDs and a plurality of apertures disposed within the array of LEDs; and
a front protective panel covering the array of LEDs, wherein the front protective panel includes a plurality of posts that extend from a rear surface of the front protective panel, wherein the plurality of posts are received within the plurality of apertures disposed within the array of LEDs,
wherein the front surface of the support structure includes a plurality of sockets that receive the plurality of posts extending through the plurality of apertures in the printed circuit board, and
wherein the foam shock absorber and the plurality of spring-biased shock absorbers in combination provide shock absorption that prevents damage to the printed circuit board when the front protective panel is impacted by a foreign object.

10. The LED display unit of claim 9 wherein the foam shock absorber comprises Ethylene Vinyl Acetate (EVA) foam.

11. The LED display unit of claim 9 wherein a thickness of the foam shock absorber ranges from about 1 inch to 2 inches.

12. The LED display unit of claim 9 wherein the front protective panel is spaced away from the array of LEDs by about 2 mm.
